(19) United States
(12) Patent Application Publication
(10) Pub. No.: US 2009/0096716 A1
(43) Pub. Date: Apr. 16, 2009

(54) DISPLAY DEVICE

(75) Inventors: Yunsik Jeong, Gumi-city (KR); Hongki Park, Gumi-city (KR)

Correspondence Address: KED & ASSOCIATES, LLP, P.O. Box 221200, Chantilly, VA, 20153-1200, US

(73) Assignee: LG Electronics Inc.

(21) Appl. No.: 11/967,705

(22) Filed: Dec. 31, 2007

(30) Foreign Application Priority Data
Sep. 12, 2007 (KR) 10-2007-0092693
Sep. 12, 2007 (KR) 10-2007-0092695

(51) Int. Cl. G06F 3/038; G09G 3/20

(52) U.S. Cl. 345/55; 345/214

(57) ABSTRACT

A display device is disclosed. The display device includes a first substrate,
a light emitting unit on the first substrate, a second substrate sealing the light emitting unit, and a seal member attaching the first substrate to the second substrate. The light emitting unit includes a first electrode, an organic film layer having a light emitting layer, and a second electrode. At least one of layers constituting the light emitting layer includes a phosphorescence material.

The seal member has an adhesive strength that lies substantially in a range between 5 and 200 kg f/cm², a glass transition temperature that lies substantially in a range between 100 and 200° C., and a water vapor permeation rate greater than 0 and equal to or less than 10⁻² g/m²/day.

This application claims the benefit of Korean Patent Application Nos. 10-2007-0092693 and 10-2007-0092695 filed on Sep. 12, 2007, which is hereby incorporated by reference.

### BACKGROUND OF THE DISCLOSURE

1. Field of the Disclosure

An exemplary embodiment relates to a display device.

2. Description of the Related Art

Due to development of a multimedia, importance of display devices such as flat panel displays (FPD) has been gradually increasing. Other displays such as a liquid crystal display (LCD), a plasma display panel (PDP), a field emission display (FED), and an organic light emitting device also being used.

An organic light emitting device may have a high response speed (of 1 ms or less), a low power consumption, and a self-luminance property. An organic light emitting device may also not have viewing problems. As such, organic light emitting device be considered as the next generation display devices.

The organic light emitting device is a display device for self-emitting in a light emitting layer that includes an organic material that may be easily deteriorated by external moisture and oxygen. Therefore, the organic light emitting device may attempt to prevent the organic material of the light emitting layer from being deteriorated.

The organic light emitting device includes a first substrate including a first electrode, an organic film including at least a light emitting layer, and a second electrode. The first substrate is sealed with a second substrate by coating a seal member on the first substrate. Then, the seal member is cured by radiating ultraviolet rays to the seal member used to attach the first to second substrates together to complete the organic light emitting device.

However, because a phase change occurred in the related art seal member during a thermal process, an adhesive strength of the related art seal member was reduced. Therefore, the reliability of the seal member for attaching the substrates cannot be maintained.

### SUMMARY OF THE DISCLOSURE

An exemplary embodiment provides a display device capable of improving the reliability of the display device.

In an aspect, a display device comprises a first substrate, a light emitting unit on the first substrate, the light emitting unit including a first electrode, an organic film layer having a light emitting layer, and a second electrode, at least one of layers constituting the light emitting layer including a phosphorescence material, a second substrate that seals the light emitting unit, and a seal member that attaches the first substrate to the second substrate, the seal member having a glass transition temperature that lies substantially in a range between 100 and 200° C.

In another aspect, a display device comprises a first substrate, a light emitting unit on the first substrate, the light emitting unit including a first electrode, an organic film layer having a light emitting layer, and a second electrode, at least one of layers constituting the light emitting layer including a phosphorescence material, a second substrate that seals the light emitting unit, and a seal member that attaches the first substrate to the second substrate, the seal member having an adhesive strength that lies substantially in a range between 5 and 200 kg f/cm².

In yet another aspect, a display device comprises a first substrate, a light emitting unit on the first substrate, the light emitting unit including a first electrode, an organic film layer having a light emitting layer, and a second electrode, at least one of layers constituting the light emitting layer including a phosphorescence material, a second substrate that seals the light emitting unit, and a seal member that attaches the first substrate to the second substrate, wherein the seal member has an adhesive strength that lies substantially in a range between 5 and 200 kg f/cm², a glass transition temperature that lies substantially in a range between 100 and 200° C., and a water vapor permeation rate greater than 0 and equal to or less than 10⁻² g/m²/day.

### BRIEF DESCRIPTION OF THE DRAWINGS

The accompanying drawings, which are included to provide a further understanding of the invention and are incorporated on and constitute a part of this specification, illustrate embodiments of the invention and together with the description serve to explain the principles of the invention. In the drawings:

FIG. 1 is a bock diagram of a display device according to an exemplary embodiment;

FIG. 2 is a plane view of the display device;

FIGS. 3A and 3B are circuit diagrams of a subpixel of the display device;

FIG. 4 is a cross-sectional view taken along line I-I′ of FIG. 2;

FIG. 5 is a diagram showing pixels with a dark defect generated;

FIGS. 6A to 6C illustrate various implementations of a color image display method in the display device;

FIG. 7 is a cross-sectional view of the display device;

FIG. 8 is a graph showing a relationship between an absorptance and an ultraviolet (UV) wavelength in a photoinitiator of a seal member of the display device.

### DETAILED DESCRIPTION OF EMBODIMENTS

Reference will now be made in detail embodiments of the invention examples of which are illustrated in the accompanying drawings.

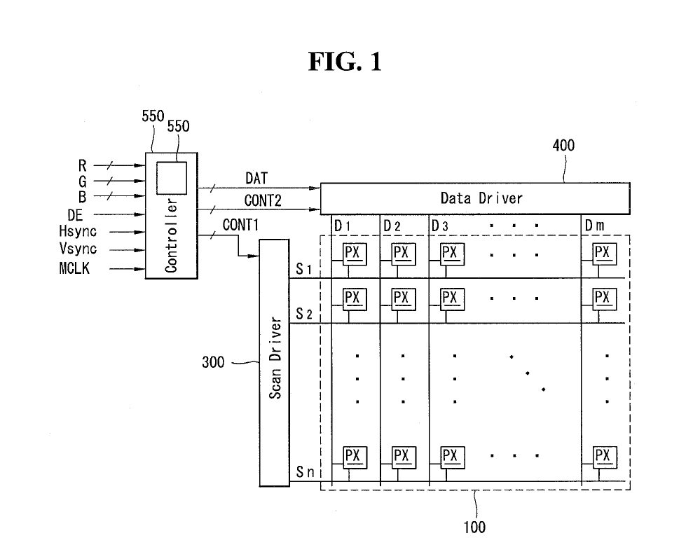

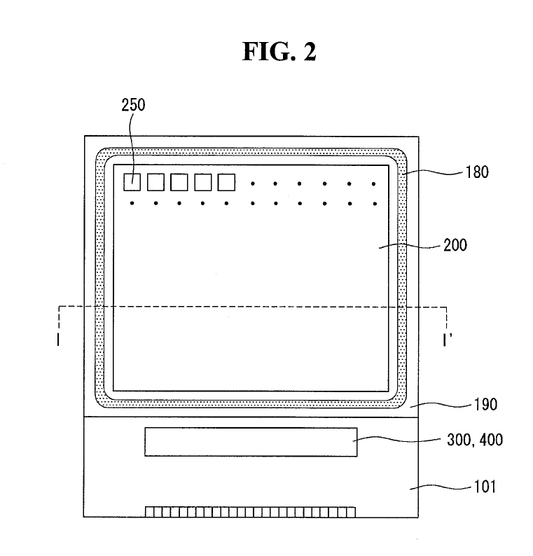

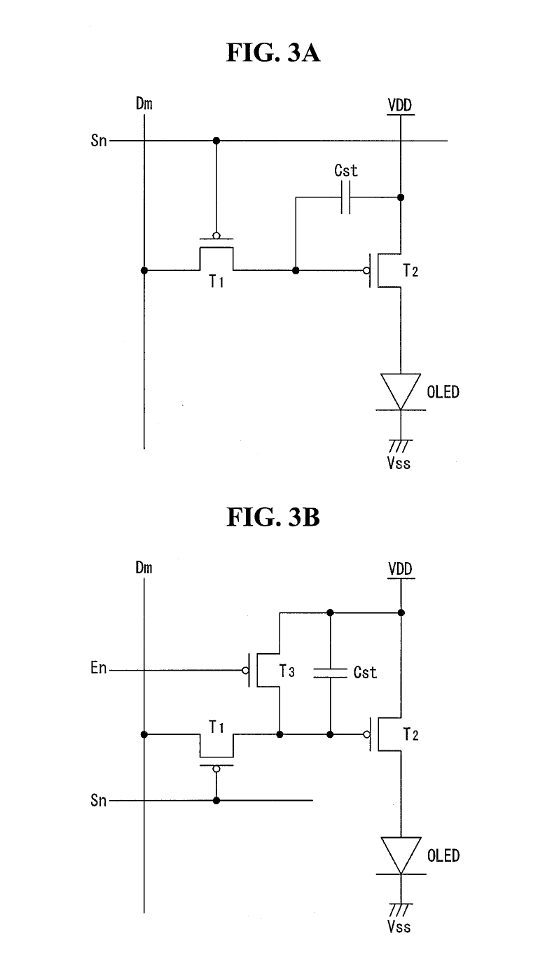

FIG. 1 is a bock diagram of a display device according to an exemplary embodiment, FIG. 2 is a plane view of the display device, and FIGS. 3A and 3B are circuit diagrams of a subpixel of the display device.

As shown in FIG. 1, the display device according to the exemplary embodiment includes a display panel 100, a scan driver 300, a data driver 400 and a controller 500.

The display panel 100 includes a plurality of signal lines S1 to Sn and D1 to Dm, a plurality of power supply lines (not shown), and a plurality of subpixels PX connected to the signal lines S1 to Sn and D1 to Dm and the power supply lines in a matrix form.

The plurality of signal lines St to Sn and D1 to Dm may include the plurality of scan lines S1 to Sn for sending scan signals and the plurality of data lines D1 to Dm for sending data signals. Each power supply line may send voltages such as a power voltage VDD to each subpixel PX.

Although the signal lines include the scan lines S1 to Sn and the data lines D1 to Dm in FIG. 1, the exemplary embodiment is not limited thereto. The signal lines may further include erase lines (not shown) for sending erase signals depending on a driving manner.

However, an erase line may not be used to send an erase signal. The erase signal may be sent through another signal line. For instance, although it is not shown, the erase signal may be supplied to the display panel 100 through the power supply line in case that the power supply line for supplying the power voltage VDD is formed.

As shown in FIG. 3A, the subpixel PX may include a switching thin film transistor T1 for sending the data signal in response to the scan signal sent through the scan line Sn, a capacitor Cst for storing the data signal, a driving thin film transistor T2 producing a driving current corresponding to a voltage difference between the data signal stored in the capacitor Cst and the power voltage VDD, and an organic light emitting diode (OLED) emitting light corresponding to the driving current.

As shown in FIG. 3B, the subpixel PX may include a switching thin film transistor T1 for sending the data signal in response to the scan signal sent through the scan line Sn, a capacitor Cst for storing the data signal, a driving thin film transistor T2 producing a driving current corresponding to a voltage difference between the data signal stored in the capacitor Cst and the power voltage VDD, an organic light emitting diode (OLED) emitting light corresponding to the driving current, and an erase switching thin film transistor T3 for erasing the data signal stored in the capacitor Cst in response to an erase signal sent through an erase line En.

When the display device is driven in a digital driving manner that represents a gray scale by dividing one frame into a plurality of subfields, the pixel circuit of FIG. 3B can control an emission time by supplying an erase signal to a subfield whose a light-emission is shorter than an addressing time. The pixel circuit of FIG. 3B has an advantage capable of reducing a lowest luminance of the display device.

A difference between driving voltages, e.g., the power voltages VDD and Vss of the display device may change depending on the size of the display panel 100 and a driving manner. A magnitude of the driving voltage is shown in the following Tables 1 and 2. Table 1 indicates a driving voltage magnitude in case of a digital driving manner, and Table 2 indicates a driving voltage magnitude in case of an analog driving manner.

TABLE 1

| Size (S) | | | |
|---|---|---|---|
| of display panel | VDD-Vss (R) | VDD-Vss (G) | VDD-Vss (B) |
| S < 3 inches | 3.5-10 (V) | 3.5-10 (V) | 3.5-12 (V) |
| 3 inches < S < 20 | 5-15 (V) | 5-15 (V) | 5-20 (V) |
| inches | | | |
| 20 inches < S | 5-20 (V) | 5-20 (V) | 5-25 (V) |

TABLE 2

| Size (S) of display panel | VDD-Vss (R, G, B) |
|---|---|
| S < 3 inches | 4~20 (V) |
| 3 inches < S < 20 inches | 5~25 (V) |
| 20 inches < S | 5~30 (V) |

Referring again to FIG. 1, the scan driver 300 is connected to the scan lines S1 to Sn of the display panel 100 to apply scan signals capable of turning on the switching thin film transistor T1 to the scan lines S1 to Sn, respectively.

The data driver 400 is connected to the data lines D1 to Dm of the display panel 100 to apply data signals indicating an output video signal DAT′ to the data lines D1 to Dm, respectively. The data driver 400 may include at least one data driving integrated circuit (IC) connected to the data lines D1 to Dm.

The data driving IC may include a shift register, a latch, a digital-to-analog (DA) converter, and an output buffer connected to one another in the order named.

When a horizontal sync start signal (STH) (or a shift clock signal) is received, the shift register can send the output video signal DAT′ to the latch in response to a data clock signal (HLCK). In case that the data driver 400 includes a plurality of data driving ICs, a shift register of a data driving IC can send a shift clock signal to a shift register of a next data driving IC.

The latch memorizes the output video signal DAT′, selects a gray voltage corresponding to the memorized output video signal DAT′ in response to a load signal, and sends the gray voltage to the output buffer.

The DA converter selects the corresponding gray voltage in response to the output video signal DAT′ and sends the gray voltage to the output buffer.

The output buffer outputs an output voltage (serving as a data signal) received from the DA converter to the data lines D1 to Dm, and maintains the output of the output voltage for 1 horizontal period (1H).

The controller 500 controls an operation of the scan driver 300 and an operation of the data driver 400. The controller 500 may include a signal conversion unit 550 that gamma-converts input video signals R, G and B into the output video signal DAT′ and produces the output video signal DAT′.

The controller 500 produces a scan control signal CONT1 and a data control signal CONT2, and the like. Then, the controller 500 outputs the scan control signal CONT1 to the scan driver 300 and outputs the data control signal CONT2 and the processed output video signal DAT′ to the data driver 400.

The controller 500 receives the input video signals R, G and B and an input control signal for controlling the display of the input video signals R, G and B from a graphic controller (not shown) outside the display device. Examples of the input control signal include a vertical sync signal Vsync, a horizontal sync signal Hsync, a main clock signal MCLK and a data enable signal DE.

Each of the driving devices 300, 400 and 500 may be directly mounted on the display panel 100 in the form of at least one IC chip, or may be attached to the display panel 100 in the form of a tape carrier package (TCP) in a state where the driving devices 300, 400 and 500 each are mounted on a flexible printed circuit film (not shown), or may be mounted on a separate printed circuit board (not shown).

Alternatively, each of the driving devices 300, 400 and 500 may be integrated on the display panel 100 together with the plurality of signal lines S1 to Sn and D1 to Dm or the thin film transistors T1, T2 and T3, and the like.

Further, the driving devices 300, 400 and 500 may be integrated into a single chip. In this case, at least one of the driving devices 300, 400 and 500 or at least one circuit element constituting the driving devices 300, 400 and 500 may be positioned outside the single chip.

As shown in FIG. 2, the display device according to the exemplary embodiment includes a first substrate 101, a second substrate 190 facing the first substrate 101, a light emitting unit 200 on the first substrate 101, a plurality of unit pixels 250 inside the light emitting unit 200, a seal member 180 positioned around the light emitting unit 200 to attach the first substrate 101 to the second substrate 190, and drivers 300 and 400 applying signals to the light emitting unit 200.

The light emitting unit 200 is an image display area. The light emitting unit 200 may include the plurality of unit pixels 250. Each of the unit pixels 250 may include three red (R), green (G), and blue (B) sub-pixels.

The drivers 300 and 400 apply signals to the light emitting unit 200. The drivers 300 and 400 may be mounted in a chip-on-glass (COG) manner.

The seal member 180 is positioned around the light emitting unit 200 to seal the light emitting 200 by attaching the first substrate 101 to the second substrate 190. The seal member 180 may be a sealant or a frit. The seal member 180 may be positioned on the first substrate 101 and surround the light emitting unit 200.

Although the seal member 180 is positioned to surround the light emitting unit 200 in FIG. 2, the exemplary embodiment is not limited thereto. The seal member 180 may be coated on the entire surface of the first substrate 101 and the light emitting unit 200.

One end of the seal member 180 may contact at least one of inorganic insulating layers on the first substrate 101, and the other end may contact the second substrate 190.

The seal member 180 may be made of a material that can be cured by ultraviolet (UV) irradiation, for example, a sealant. The seal member 180 may include epoxy resin or acrylic resin. A glass transition temperature (Tg) of the seal member 180 may lie substantially in a range between 100 and 200° C., or 120 and 180° C. The seal member 180 may be cured at a UV wavelength range. More specifically, the seal member 180 may be cured at a UV wavelength range of approximately 170 nm to 250 mm.

The seal member 180 may use a frit. The frit may be made of a material that can be cured by infrared (1R) irradiation. Examples of the material include K₂O, Fe₂O₃, Sb₂O₃, ZnO, P₂O₅, V₂O₅, TiO₂, Al₂O₃, WO₃, Bi₂O₃, SiO₂, B₂O₃, PbO, BaO, TeO as a principal component.

The frit may further include a filler. The filler may include a low expansion ceramic powder such as codierite, zirconyl phosphate, β-eucryptite, β-spodumene, zircon, alumina, mullite, silica, β-quartz solid solution, zinc silicate, aluminum titanate. The filler can operate so that a thermal expansion coefficient of a glass substrate corresponds with a thermal expansion coefficient of the frit.

The frit may further include a transition metal. The transition metal can adjust a thermal expansion characteristic of the frit and an absorption characteristic depending on a frequency of a laser to which will be applied later. Examples of the transition metal include chromium (Cr), iron (Fe), manganese (Mn), cobalt (Co), copper (Cu), vanadium (V).

The frit may further include ZnSiO₄, PbTiO₃, ZrO₂, eucryptite as an additive.

The frit may be formed by coating a frit paste including the above materials on the second substrate 190 using a dispensing method or a screen printing method.

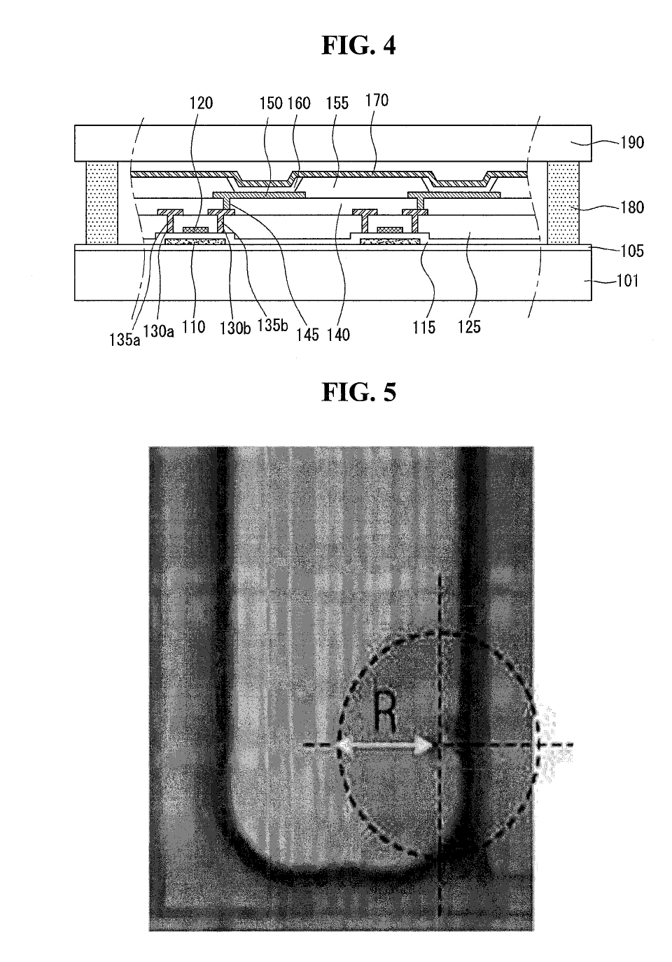

FIG. 4 is a cross-sectional view taken along line I-I′ of FIG. 2.

As shown in FIG. 4, a buffer layer 105 is positioned on the substrate 101. The buffer layer 105 prevents impurities (e.g., alkali ions discharged from the first substrate 101) from being introduced during formation of the thin film transistor in a succeeding process. The buffer layer 105 may be selectively formed using silicon oxide (SiO₂) and silicon nitride (SiNx), or using other materials.

A semiconductor layer 110 is positioned on the buffer layer 105. The semiconductor layer 110 may comprise amorphous semiconductor or polycrystalline silicon formed by curing the amorphous semiconductor. Although it is not shown, the semiconductor layer 110 may include a channel region, a source region, and a drain region. Also, the source region and the drain region may be doped with P-type or N-type impurity.

A gate insulating layer 115 is positioned on the first substrate 101 including the semiconductor layer 110. The gate insulating layer 115 may be selectively formed using silicon oxide (SiO₂) and silicon nitride (SiNx), or using other materials.

A gate electrode 120 is positioned on a predetermined area of the semiconductor layer 110, that is, the gate insulating layer 115 corresponding to the channel region. The gate electrode 120 may include one of aluminum (Al), aluminum alloy, titanium (Ti), silver (Ag), molybdenum (Mo), molybdenum alloy, tungsten (W), and tungsten silicide (WSi₂). However, the gate electrode 120 is not limited thereto.

An interlayer insulating layer 125 is positioned on the first substrate 101 including the gate electrode 120. The interlayer insulating layer 135 may be an organic film layer or an inorganic film layer, or a composite film layer thereof.

In case that the interlayer insulating layer 125 is an inorganic film layer, the interlayer insulating layer 125 may comprise silicon nitride (SiNx) or silicate on glass (SOG). In case that the interlayer insulating layer 125 is an organic film layer, the interlayer insulating layer 125 may comprise acrylic resin, polyamide resin, or benzecyclobutence (BCB) resin. However, the interlayer insulating layer 125 is not limited thereto.

Contac holes 130a and 130b pass through the interlayer insulating layer 125 and the gate insulating layer 115 to expose a predetermined area of the semiconductor layer 110.

A source electrode 135a and a drain electrode 235b are electrically connected to the semiconductor layer 110 through the contact holes 130a and 130b. The source electrode and the drain electrode 135a and 135b may comprise a low resistance material for reducing line resistance. Also, the source electrode and the drain electrode 135a and 135b may have a multi-layered structure formed of molybdenum tungsten (MoW), titanium (Ti), aluminum (Al), or aluminum alloy (Al alloy). The multi-layered structure may have a triple-layer structure including Ti/Al/Ti, Mo/Al/Mo, or MoW/Al/MoW.

A planarization layer 140 is positioned on the source electrode 135a and the drain electrode 135b. The planarization layer 140 may include an organic material such as benzocyclobuten (BCB) resin, acrylic resin, or polyamide resin. However, the planarization layer 140 is not limited thereto.

A first electrode 150 is positioned on the planarization layer 140 to be electrically connected to the drain electrode 135b through a via hole 145 in the planarization layer 140. The first electrode 150 may be an anode electrode and include a transparent conductive layer such as Indium Tin Oxide (ITO) or Indium Zinc Oxide (IZO). The first electrode 150 may further include a reflection layer under the transparent conductive layer, and thus can have a stacking structure such as ITO/Ag/ATO or ITO/Ag.

A bank layer 155 is positioned on the first substrate 101 comprising the first electrode 150 to expose a predetermined area of the first electrode 150. The bank layer 250 may comprise an organic material such as benzocyclobuten (BCB) resin, acrylic resin, or polyamide resin. However, the bank layer 155 is not limited thereto.

An organic film layer 160 is positioned on an exposed portion of the first electrode 150 by the band layer 155. The organic film layer 160 includes a light emitting layer. The organic film layer 160 further includes an electron injection layer, an electron transport layer, a hole transport layer, or an hole injection layer on or under the light emitting layer.

At least one of layers constituting the organic film layer may further include an inorganic material. The inorganic film layer may further include metal compound. The metal compound may comprise alkali metal or alkali earth metal. The metal compound comprising the alkali metal or the alkali earth metal may be one selected from the group consisting of LiF, NaF, KF, RbF, CsF, FrF, BeF2, MgF2, CaF2, SrF2, BaF2, and RaF2.

In at least one organic film layer including the inorganic material, the highest unoccupied molecular orbital level of the inorganic material may operate to reduce the lowest unoccupied molecular orbital level of an organic material forming the organic film layer. Particularly, LiF improves the electron injecting characteristics of the light emitting layer by forming strong dipole, and thus can improve the light emitting efficiency and can lower a driving voltage.

Therefore, the inorganic material in at least one of the organic film layers comprising inorganic material balances the holes and electron injected into the light emitting layer by making the hopping of electrons injected into the light emitting layer from the second electrode easy. Therefore, the inorganic material improves the light emitting efficiency.

A second electrode 170 is positioned on the first substrate 101 comprising the organic film layer 160. The second electrode 170 may be a cathode electrode for supplying electrons to the light emitting layer. The second electrode 170 may include magnesium (Mg), silver (Ag), calcium (Ca), aluminum (Al), or an alloy thereof.

The seal member 180 attaches the first substrate 101 to the second substrate 190. The seal member 180 directly contacts an inorganic insulating layer on the first substrate 101. While the buffer layer 105 being an inorganic insulating layer contacts the seal member 180 in the exemplary embodiment, the buffer layer 105 may contact the gate insulating layer or the interlayer insulating layer.

In other words, the seal member 180 contacts an inorganic insulating layer such as the buffer layer, the gate insulating layer, or the interlayer insulating layer, thereby improving an adhesive strength between the seal member 180 and the first substrate 101.

The seal member 180 may be made of material that can be cured by UV irradiation. The seal member 180 may include epoxy resin or acrylic resin. Furthermore, the seal member 180 may further include a photoinitiator for polymerization by absorbing UV energy during UV irradiation. The seal member 180 may include a photoinitiator of 1 to 5 parts by weight based on total weight of the seal member 180.

The glass transition temperature Tg of the seal member 180 may lie substantially in a range between 100 and 200° C., or 120 and 180° C.

The seal member 180 has the glass transition temperature equal to or higher than 100° C. so as to prevent the seal member 180 being deformed by a phase change in the seal member 180 during a thermal process. The deformation of the seal member 180 reduces an adhesive strength between the substrates.

Also, the seal member 180 has the glass transition temperature equal to or lower than 200° C. so as to solve the processing difficulty of keeping a high temperature environment during a dispensing process for coating the seal member 180.

While a top-emission type organic light emitting device was described in the exemplary embodiment, the display device according to the exemplary embodiment may be applied to a bottom-emission type organic light emitting device.

Table 3 shows glass transition temperatures of seal members in a display device. The seal members A to D denote seal members classified depending on a type.

TABLE 3

| | Seal | Seal | Seal | Seal |
|---|---|---|---|---|
| | member A | member B | member C | member D |
| Glass | 120 | 180 | 145 | 144 |
| transition | | | | |
| temperature | | | | |
| (Tg) ° C. | | | | |

Table 3 shows that the seal members of the display device have the glass transition temperatures of 100 to 200° C. Further, the glass transition temperatures of the seal member may lie substantially in a range between 120 and 180° C.

Table 4 shows results of testing the reliability of an organic light emitting device comprising seal members each having a different glass transition temperature, and FIG. 5 is a diagram illustrating a dark defect generated at a pixel.

An organic light emitting device is sealed using each of a seal member 80 having a glass transition temperature of 80° C. and a seal member 120 having a glass transition temperature of 120° C. Then, Table 4 shows a measuring result of a radius of a dark defect generated when the sealed organic light emitting device is exposed for 500 hours under the atmosphere of a temperature of 80° C. and a humidity of 95%.

TABLE 4

| Time elapsed | Radius of dark defect of | Radius of dark defect of |
|---|---|---|
| (hours) | seal member 80 (μm) | seal member 120 (μm) |
| 100 | 6 | 3 |
| 200 | 8.6 | 4.5 |
| 300 | 9.7 | 6.2 |
| 400 | 11.7 | 7.3 |
| 500 | 13.5 | 8 |

As indicated in Table 4, the radius of a dark defect of the seal member 80 having the glass transition temperature of 80° C. increases at a faster speed than the radius of the dark defect of the seal member 120 having the glass transition temperature of 120° C.

Since the organic light emitting device comprises elements made of an organic material that is easily deteriorated by moisture or oxygen, pixels are easily deteriorated due to a reduction in the adhesive strength of the seal member. Therefore, the dark defect is easily generated.

Therefore, a seal member having a glass transition temperature of 100 to 200° C. is used in the display device according to the exemplary embodiment so as to prevent the adhesive strength from being reduced due to the phase change in the seal member during a thermal process and so as to prevent a light emitting layer from being deteriorated by preventing moisture or oxygen from penetrating.

The adhesive strength of the seal member 180 may lie substantially in a range between 5 and 200 kg f/cm², or 20 and 150 kg f/cm².

The adhesive strength of the seal member 180 may depend on a material of the first substrate 101. If the first substrate 101 is a glass, the adhesive strength between the first substrate 101 and the seal member 180 may lie substantially in a range between 5 to 20 kg f/cm². Otherwise, if the first substrate 101 is a metal, the adhesive strength between the first substrate 101 and the seal member 180 may lie substantially in a range between 15 to 200 kg f/cm².

The adhesive strength of the seal member 180 is equal to greater than 5 kg f/cm² so as to improve impact resistance by preventing the seal member from easily coming out by external impact after the display device is completely manufactured. The adhesive strength of the seal member 180 may be equal to or smaller than about 200 kg f/cm² because of a reason of the process limitation although the greater the adhesive strength of the seal member 180 is better.

As described above, the display device according to the exemplary embodiment includes the seal member having the adhesive strength of 5 to 200 kg f/cm². Therefore, the seal member is prevented from coming off by external impact, thereby improving the reliability of the display device.

The seal member 180 may have a water vapor permeation rate greater than 0 and equal to or less than 10⁻² g/m²/day. An inorganic film layer has generally a water vapor permeation rate of 10⁻¹ g/m²/day.

It is advantageous that a display device has generally a water vapor permeation rate of 10⁻² g/m²/day. The display device according to the exemplary embodiment uses the sealing material having a water vapor permeation rate more than 10⁻² g/m²/day and an oxygen vapor permeation rate more than 10⁻³ g/m²/day, and thus can have excellent moisture and oxygen prevention properties.

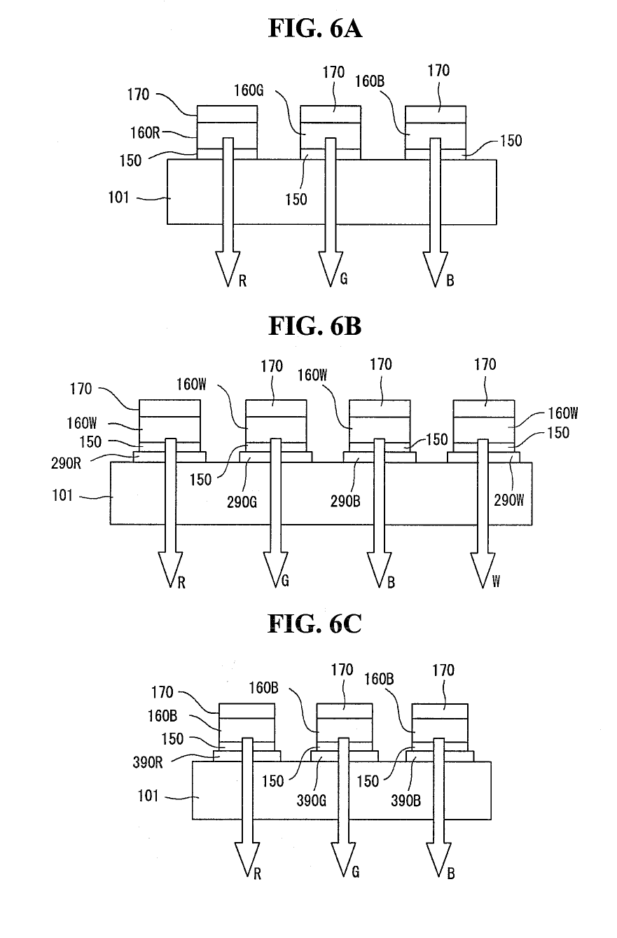

FIGS. 6A to 6C illustrate various implementations of a color image display method in the display device.

FIG. 6A illustrates a color image display method in a display device separately including a red light emitting layer 160R, a green light emitting layer 160G and a blue light emitting layer 160B which emit red, green and blue light, respectively.

The red, green and blue light produced by the red, green and blue light emitting layers 160R, 160G and 160B is mixed to display a color image.

It may be understood in FIG. 6A that the red, green and blue light emitting layers 160R, 160G and 160B each include an electron transport layer, a hole transport layer, and the like, on upper and lower portions thereof. It is possible to variously change the arrangement and the structure between the additional layers such as the electron transport layer and the hole transport layer and each of the red, green and blue light emitting layers 160R, 160G and 160B.

FIG. 6B illustrates a color image display method in a display device including a white light emitting layer 160W, a red color filter 290R, a green color filter 290G, a blue color filter 290B, and a white color filter 290W.

As shown in FIG. 6B, the red color filter 290R, the green color filter 290G, the blue color filter 290B, and the white color filter 290W each transmit white light produced by the white light emitting layer 160W to produce red light, green light, blue light, and white light. The red, green, blue, and white light is mixed to display a color image. The white color filter 290W may be removed depending on color sensitivity of the white light produced by the white light emitting layer 160W and combination of the white light and the red, green and blue light.

While FIG. 6B has illustrated the color display method of four subpixels using combination of the red, green, blue, and white light, a color display method of three subpixels using combination of the red, green, and blue light may be used.

It may be understood in FIG. 6B that the white light emitting layer 160W includes an electron transport layer, a hole transport layer, and the like, on upper and lower portions thereof. It is possible to variously change the arrangement and the structure between the additional layers such as the electron transport layer and the hole transport layer and the white light emitting layer 160W.

FIG. 6C illustrates a color image display method in a display device including a blue light emitting layer 160B, a red color change medium 390R, a green color change medium 390G, a blue color change medium 390B.

As shown in FIG. 6C, the red color change medium 390R, the green color change medium 390G, and the blue color change medium 390B each transmit blue light produced by the blue light emitting layer 160B to produce red light, green light and blue light. The red, green and blue light is mixed to display a color image.

The blue color change medium 390B may be removed depending on color sensitivity of the blue light produced by the blue light emitting layer 160B and combination of the blue light and the red and green light.

It may be understood in FIG. 6C that the blue light emitting layer 160B includes an electron transport layer, a hole transport layer, and the like, on upper and lower portions thereof. It is possible to variously change the arrangement and the structure between the additional layers such as the electron transport layer and the hole transport layer and the blue light emitting layer 160B.

While FIGS. 6A and 6B have illustrated and described the display device having a bottom emission structure, the exemplary embodiment is not limited thereto. The display device according to the exemplary embodiment may have a top emission structure, and thus the structure of the display device according to the exemplary embodiment may be changed depending on the top emission structure.

While FIGS. 6A to 6C have illustrated and described three kinds of color image display method, the exemplary embodiment is not limited thereto. The exemplary embodiment may use various kinds of color image display method whenever necessary.

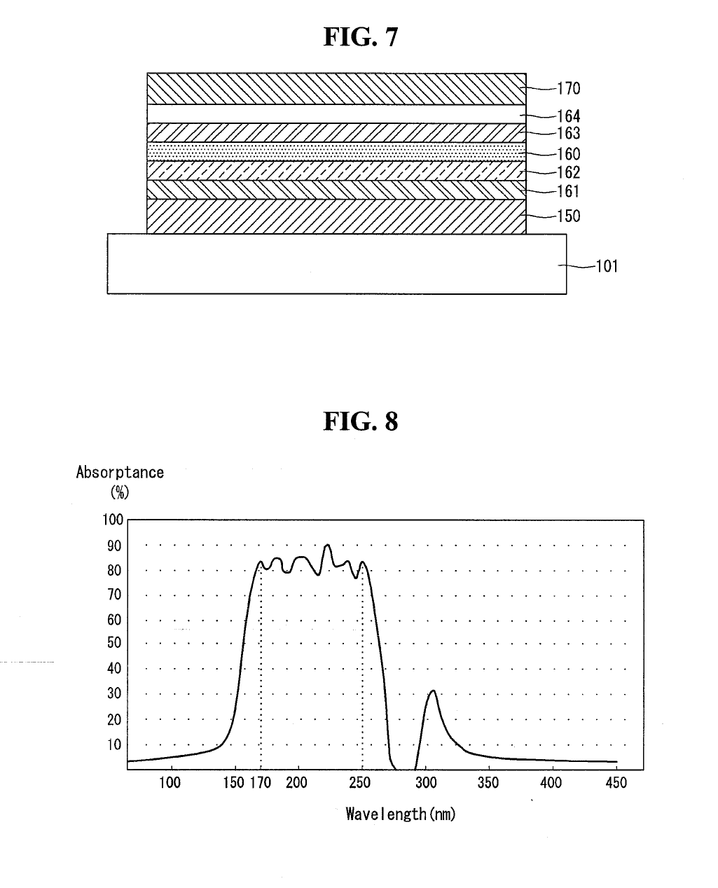

FIG. 7 is a cross-sectional view of the display device.

As shown in FIG. 7, the display device according to the exemplary embodiment includes the substrate 101, the first electrode 150 positioned on the substrate 101, a hole injection layer 161 positioned on the first electrode 150, a hole transport layer 162, a light emitting layer 160, an electron transport layer 163, an electron injection layer 164, and the second electrode 170 positioned on the electron injection layer 164.

The hole injection layer 161 may function to facilitate the injection of holes from the first electrode 150 to the light emitting layer 160. The hole injection layer 161 may be formed of at least one selected from the group consisting of copper phthalocyanine (CuPc), PEDOT(poly(3,4)-ethylenedioxythiophene), polyaniline (PANI) and NPD(N,N-dinaphthyl-N,N′-diphenyl benzidine), but is not limited thereto. The hole injection layer 161 may be formed using an evaporation method or a spin coating method.

The hole transport layer 162 functions to smoothly transport holes. The hole transport layer 162 may be formed from at least one selected from the group consisting of NPD(N,N-dinaphthyl-N,N′-diphenyl benzidine), TPD(N,N′-bis-(3-methylphenyl)-N,N′-bis-(phenyl)-benzidine, s-TAD and MTDATA(4,4′,4″-Tris(N-3-methylphenyl-N-phenyl-amino)-triphenylamine), but is not limited thereto. The hole transport layer 162 may be formed using an evaporation method or a spin coating method.

The light emitting layer 160 may be formed of a material capable of producing red, green, blue or white light, for example, a phosphorescence material or a fluorescence material.

In case that the light emitting layer 160 emits red light, the light emitting layer 160 includes a host material including carbazole biphenyl (CBP) or N,N-dicarbazolyl-3,5-benzene (mCP). Further, the light emitting layer 160 may be formed of a phosphorescence material including a dopant material including any one selected from the group consisting of PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium) and PtOEP(octaethylporphyrin platinum) or a fluorescence material including PBD:Eu(DBM)3(Phen) or Perylene, but is not limited thereto.

In case that the light emitting layer 160 emits green light, the light emitting layer 160 includes a host material including CBP or mCP. Further, the light emitting layer 160 may be formed of a phosphorescence material including a dopant material including Ir(ppy)3(fac tris(2-phenylpyridine)iridium) or a fluorescence material including Alq3(tris(8-hydroxyquinolino)aluminum), but is not limited thereto.

In case that the light emitting layer 160 emits blue light, the light emitting layer 160 includes a host material including CBP or mCP. Further, the light emitting layer 160 may be formed of a phosphorescence material including a dopant material including (4,6-F2 ppy)2Irpic or a fluorescence material including any one selected from the group consisting of spiro-DPVBi, spiro-6P, distyryl-benzene (DSB), distyryl-arylene (DSA), PFO-based polymers, PPV-based polymers and a combination thereof, but is not limited thereto.

The electron transport layer 163 functions to facilitate the transportation of electrons. The electron transport layer 163 may be formed of at least one selected from the group consisting of Alq3(tris(8-hydroxyquinolino)aluminum, PBD, TAZ, spiro-PBD, BAlq, and SAlq, but is not limited thereto. The electron transport layer 163 may be formed using an evaporation method or a spin coating method.

The electron transport layer 163 can also function to prevent holes, which are injected from the first electrode 150 and then pass through the light emitting layer 160, from moving to the second electrode 170. In other words, the electron transport layer 163 serves as a hole stop layer, which facilitates the coupling of holes and electrons in the light emitting layer 160.

The electron injection layer 164 functions to facilitate the injection of electrons. The electron injection layer 164 may be formed of Alq3(tris(8-hydroxyquinolino)aluminum), PBD, TAZ, spiro-PBD, BAlq or SAlq, but is not limited thereto.

The electron injection layer 164 may be formed of an organic material and an inorganic material forming the electron injection layer 164 through a vacuum evaporation method.

The hole injection layer 161 or the electron injection layer 164 may further include an inorganic material. The inorganic material may further include a metal compound. The metal compound may include alkali metal or alkaline earth metal.

The metal compound including the alkali metal or the alkaline earth metal may include at least one selected from the group consisting of LiQ, LiF, NaF, KF, RbF, CsF, FrF, BeF₂, MgF₂, CaF₂, SrF₂, BaF₂, and RaF₂, but is not limited thereto.

Thus, the inorganic material inside the electron injection layer 164 facilitates hopping of electrons injected from the second electrode 170 to the light emitting layer 160, so that holes and electrons injected into the light emitting layer 160 are balanced. Accordingly, light emitting efficiency can be improved.

Further, the inorganic material inside the hole injection layer 161 reduces the mobility of holes injected from the first electrode 150 to the light emitting layer 160, so that holes and electrons injected into the light emitting layer 160 are balanced. Accordingly, emission efficiency can be improved.

At least one of the electron injection layer 164, the electron transport layer 163, the hole transport layer 162, the hole injection layer 161 may be omitted.

FIG. 8 is a graph showing a relationship between an absorptance and an ultraviolet (UV) wavelength in a photoinitiator of a seal member of the display device.

In FIG. 8, a horizontal axis denotes a wavelength, and a vertical axis denotes absorptance of a photoinitiator.

As shown in FIG. 8, the photoinitiator of the seal member 180 has a high UV absorptance equal to or more than about 85% at wavelength of approximately 170 to 250 nm. That is, the seal member 180 can be cured at the UV wavelength of approximately 170 nm to 250 nm.

The graph means that the photoinitiator of the seal member 180 absorbs more UV rays at the UV wavelength of approximately 170 nm to 250 nm. In more detail, the polymerization of the photoinitiator actively progresses at a wavelength of approximately 170 nm although the polymerization of the photoinitiator starts by irradiating UV rays. That is, the seal member starts to be cured by radiating UV rays at wavelength of approximately 170 nm.

The UV absorptance of the photoinitiator is very active until the wavelength reaches approximately 250 nm. However, the UV absorptance is abruptly reduced at a wavelength equal to or more than about 250 mm, and the seal member is no longer cured.

Therefore, the seal member of the display device according to the exemplary embodiment is cured at a wavelength of approximately 170 nm to 250 nm.

As described above, since the display device according to the exemplary embodiment includes the seal member having a glass transition temperature of 100 to 200° C., a reduction in an adhesive strength of the seal member caused by the phase change of the seal member can be prevented. Also, the seal member is prevented from coming off by directly connecting the seal member with an inorganic film layer having superior adhesive property. Therefore, the adhesive of the substrates can be improved.

The display device according to the exemplary embodiment includes the seal member having the adhesive strength of about 5 to 200 kg f/cm². Therefore, the seal member is prevented from coming off by the external impact. Also, the seal member is prevented from coming off by directly coming contact with an inorganic film layer having excellent adhesive property. Therefore, the adhesive strength between the substrates can be improved. As a result, the reliability of the display device can be improved.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art.

What is claimed is:

1. A display device comprising:
a first substrate;
a light emitting unit on the first substrate, the light emitting unit including a first electrode, an organic film layer having a light emitting layer, and a second electrode, at least one of layers constituting the light emitting layer including a phosphorescence material;
a second substrate that seals the light emitting unit; and
a seal member that attaches the first substrate to the second substrate, the seal member having a glass transition temperature that lies substantially in a range between 100° C. and 200° C.

2. The display device of claim 1, wherein the glass transition temperature of the seal member lies substantially in a range between 120° C. and 180° C.

3. The display device of claim 1, further comprising a thin film transistor on the substrate, the thin film transistor including a semiconductor layer, a gate insulating layer, a gate electrode, an interlayer insulating layer, a source electrode, and a drain electrode.

4. The display device of claim 1, further comprising at least one inorganic insulating layer on the substrate,
wherein the seal member contacts the inorganic insulating layer.

5. The display device of claim 1, wherein the seal member is cured at a wavelength of approximately 170 nm to 250 nm.

6. The display device of claim 1, wherein the seal member is positioned around the light emitting unit.

7. The display device of claim 1, wherein the seal member includes epoxy resin or acrylic resin.

8. The display device of claim 1, wherein the first electrode includes a transparent conductive layer, and a reflection layer under the transparent conductive layer.

9. The display device of claim 1, wherein the seal member is a sealant or a frit.

10. A display device comprising:
a first substrate;
a light emitting unit on the first substrate, the light emitting unit including a first electrode, an organic film layer having a light emitting layer, and a second electrode, at least one of layers constituting the light emitting layer including a phosphorescence material;
a second substrate that seals the light emitting unit; and
a seal member that attaches the first substrate to the second substrate, the seal member having an adhesive strength that lies substantially in a range between 5 and 200 kg f/cm².

11. The display device of claim 10, wherein the adhesive strength of the seal member lies substantially in a range between 20 and 150 kg f/cm².

12. The display device of claim 10, further comprising a thin film transistor on the substrate, the thin film transistor including a semiconductor layer, a gate insulating layer, a gate electrode, an interlayer insulating layer, a source electrode, and a drain electrode.

13. The display device of claim 10, wherein the seal member includes epoxy resin or acrylic resin.

14. The display device of claim 10, wherein the seal member is cured at a wavelength of approximately 170 nm to 250 nm.

15. The display device of claim 10, wherein the seal member is positioned around the light emitting unit.

16. The display device of claim 10, wherein the first electrode includes a transparent conductive layer, and a reflection layer under the transparent conductive layer.

17. The display device of claim 10, further comprising at least one inorganic insulating layer on the substrate,
wherein the seal member contacts the inorganic insulating layer.

18. The display device of claim 10, wherein the seal member is a sealant or a frit.

19. A display device comprising:
a first substrate;
a light emitting unit on the first substrate, the light emitting unit including a first electrode, an organic film layer having a light emitting layer, and a second electrode, at least one of layers constituting the light emitting layer including a phosphorescence material;
a second substrate that seals the light emitting unit; and a seal member that attaches the first substrate to the second substrate,
wherein the seal member has an adhesive strength that lies substantially in a range between 5 and 200 kg f/cm², a glass transition temperature that lies substantially in a range between 100° C. and 200° C., and a water vapor permeation rate greater than 0 and equal to or less than 10⁻² g/m²/day.

20. The display device of claim 19, wherein the seal member is a sealant or a frit.
